(19) United States
(12) Patent Application Publication
(10) Pub. No.: US 2025/0264627 A1
(43) Pub. Date: Aug. 21, 2025

(54) PROXIMITY SENSOR

(71) Applicant: Keyence Corporation, Osaka (JP)

(72) Inventors: Hiroshi KASHIMA, Osaka (JP); Yasunori KAWAGUCHI, Osaka (JP); Satsuki TANAKA, Osaka (JP)

(73) Assignee: Keyence Corporation, Osaka (JP)

(21) Appl. No.: 19/015,892

(22) Filed: Jan. 10, 2025

(30) Foreign Application Priority Data
Feb. 16, 2024 (JP) 2024-022088

(51) Int. Cl. G01V 3/10; H05K 9/00

(52) U.S. Cl. CPC G01V 3/101; H05K 9/0083; H05K 9/0084; H05K 9/0086

(57) ABSTRACT

Provided is a proximity sensor capable of sufficiently extending a detection distance by suppressing an influence of embedded metal. A coil of a proximity sensor includes a first coil and a second coil. The second coil is disposed concentrically with the first coil. The proximity sensor detects a detection object on the basis of a change in voltage or current generated in each of the first coil and the second coil. The coil wire of the first coil is electrically connected to the in-head substrate through direct bonding.

### CROSS-REFERENCE TO RELATED APPLICATIONS

The present application claims foreign priority based on Japanese Patent Application No. 2024-022088, filed Feb. 16, 2024, the contents of which are incorporated herein by reference.

### BACKGROUND OF THE INVENTION

### 1. Technical Field

The invention relates to a proximity sensor.

### 2. Description of the Related Art

JP 2018-152320 A discloses a proximity sensor. The proximity sensor described in JP 2018-152320 A reduces an influence of a change in coil characteristics and the like.

As illustrated in FIG. 3 of JP 2018-152320 A, the proximity sensor of JP 2018-152320 A is used by being embedded in nuts and washers of reference numerals 7 to 9.

### SUMMARY OF THE INVENTION

Meanwhile, the proximity sensor may fail if it comes into contact with an object to be detected (hereinafter, the detection object) and its peripheral members. For this reason, the proximity sensor is required to extend a distance to be detected (hereinafter, the detection distance) in order to avoid contact with the detection object or the like.

In order to extend the detection distance, the proximity sensor also needs to detect a weak change in the reception waveform. However, since the proximity sensor described in JP 2018-152320 A cannot detect a weak change in the reception waveform due to the influence of an embedded nut, a washer, or the like (hereinafter, an embedded metal), the detection distance cannot be sufficiently extended.

The invention has been made in view of the above problems, and an object thereof is to provide a proximity sensor capable of sufficiently extending a detection distance by suppressing an influence of embedded metal.

According to one aspect of the invention, a proximity sensor includes a coil, a ferrite core, a head housing, and an in-head substrate. The coil generates a magnetic field by an excitation current. The ferrite core guides a magnetic field generated from the coil. The head housing accommodates the coil and the ferrite core. The in-head substrate is accommodated in the head housing. The coil includes a first coil and a second coil. The second coil is disposed concentrically with the first coil. The proximity sensor further includes a transmission circuit, a reception circuit, and a control circuit. The transmission circuit periodically applies a pulsed excitation current to the coil. The reception circuit detects a voltage or a current generated in each of the first coil and the second coil by the magnetic field which is changed by the detection object. The control circuit detects the detection object on the basis of the change in the voltage or the current generated in at least one of the first coil and the second coil detected by the reception circuit. The coil wire of the first coil is electrically connected to the in-head substrate through direct bonding.

According to another aspect of the invention, a proximity sensor includes a coil, a ferrite core, a head housing, a cable, and an amplifier housing. The coil generates a magnetic field by an excitation current. The ferrite core guides a magnetic field generated from the coil. The head housing accommodates the coil and the ferrite core. The cable extends from the head housing. The amplifier housing is connected to the head housing via a cable. The coil includes a first coil and a second coil. The second coil is disposed concentrically with the first coil. The proximity sensor further includes a transmission circuit, a reception circuit, and a control circuit. The transmission circuit periodically applies a pulsed excitation current to the coil. The reception circuit detects a voltage or a current generated in at least one of the first coil and the second coil by the magnetic field which is changed by the detection object. The control circuit detects the detection object on the basis of the change in the voltage or the current generated in each of the first coil and the second coil detected by the reception circuit. The coil wire of the first coil is electrically connected to the cable through direct bonding.

According to still another aspect of the invention, a proximity sensor includes a coil, a ferrite core, and a head housing. The coil generates a magnetic field by an excitation current. The ferrite core guides a magnetic field generated from the coil. The head housing accommodates the coil and the ferrite core. The coil includes a first coil and a second coil. The second coil is disposed outside the first coil in the radial direction. The proximity sensor further includes a transmission circuit, a reception circuit, and a control circuit. The transmission circuit periodically applies a pulsed excitation current to the coil. The reception circuit detects a voltage or a current generated in each of the first coil and the second coil by the magnetic field which is changed by the detection object. The control circuit detects the detection object on the basis of the change in the voltage or the current generated in at least one of the first coil and the second coil detected by the reception circuit. In the head housing, a diameter of a surface facing the detection object is less than 8 mm. The number of windings of the first coil is 100 or more.

According to the proximity sensor of the invention, the detection distance can be sufficiently extended by suppressing the influence of the embedded metal.

### BRIEF DESCRIPTION OF THE DRAWINGS

FIG. 1 is an external view of a proximity sensor;

FIG. 2 is an external view of the proximity sensor in a used state;

FIG. 3 is a perspective view illustrating a bonding state between a coil wire and a substrate electrode;

FIG. 4 is a sectional view taken along line IV-IV of FIG. 3;

FIG. 5 is a view illustrating wiring of a coil wire from a first coil to a substrate electrode;

FIG. 6 is a view illustrating wiring of a coil wire from a second coil to a substrate electrode;

FIG. 7 is an exploded perspective view from a coil constituting the proximity sensor to an in-head substrate;

FIG. 8 is an exploded perspective view of components accommodated in a head housing of the proximity sensor;

FIG. 9 is a block diagram for explaining a main circuit configuration of the proximity sensor;

FIG. 10 is a diagram schematically illustrating magnetic flux lines around a first coil and a second coil;

FIG. 11 is an exploded perspective view for explaining the electric shield and the magnetic shield in detail;

FIG. 12 is a magnetic flux diagram in a case where the shaft body of the ferrite core is thin; and

FIG. 13 is a magnetic flux diagram in a case where the shaft body of the ferrite core is not thin.

### DETAILED DESCRIPTION

Hereinafter, embodiments of the invention will be described with reference to the drawings. Note that, in the drawings, the same or corresponding portions are denoted by the same reference numerals, and the description thereof will not be repeated. In the following description, terms meaning a position or a direction such as “upper”, “lower”, “left”, and “right” may be used. These terms are used for convenience to facilitate understanding of the embodiments, and are not related to the direction in which they are actually implemented unless otherwise expressly stated.

Hereinafter, a proximity sensor 100 according to an embodiment of the invention will be described with reference to the drawings.

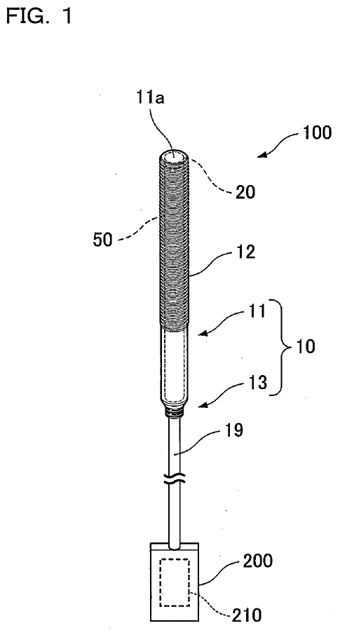

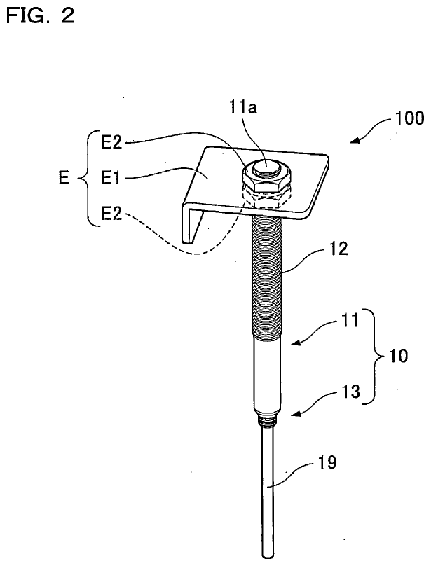

First, a situation in which a proximity sensor 100 is used will be described with reference to FIGS. 1 and 2. FIG. 1 is an external view of the proximity sensor 100. FIG. 2 is an external view of the proximity sensor 100 in a used state.

As illustrated in FIG. 1, the proximity sensor 100 has a shape (shield type) that can be fixed by a nut or the like by forming an outer screw 12 on a side surface. The outer screw 12 is formed on an outer surface of a housing body 11 of a head housing 10 disposed near the detection object. The head housing 10 is made of metal, and a head front surface portion 11a (the upper end portion in FIG. 1) facing the detection object is also made of metal. If the head front surface portion 11a is made of metal, the proximity sensor 100 is less likely to be damaged even if the head front surface portion 11a comes into contact with an object in the surrounding environment such as a detection object.

In the present embodiment, the head housing 10 has a cylindrical shape, and the head front surface portion 11a has a circular shape. The diameter of the head housing 10 of the present embodiment is small (small diameter). For example, the diameter of the head front surface portion 11a (a surface facing the detection object) is less than 8 mm.

Inside the head housing 10, a coil 20 for generating a magnetic field and an in-head substrate 50 electrically connected to the coil 20 are disposed. The proximity sensor 100 of the present embodiment uses metal as a detection object. An eddy current is induced in the metal detection object by receiving the magnetic field generated from the coil 20. The proximity sensor 100 detects a magnetic field (magnetic flux) generated from an eddy current generated in the detection object.

The in-head substrate 50 is electrically connected to the cable 19. The cable 19 extends from the inside of the head housing 10 to the outside of the head housing 10 through a head base end 13. The cable 19 is connected to an amplifier housing 200. The amplifier housing 200 accommodates an amplifier unit 210. The amplifier unit 210 amplifies the electric signal transmitted from the coil 20 through the cable 19 and transmits the amplified electric signal to an external device (such as a computer). In addition, the amplifier unit 210 supplies power for operating the coil 20 to the coil 20 through the cable 19.

As illustrated in FIG. 2, the proximity sensor 100 is fixed to a mounting bracket E1 with a double nut E2, for example. That is, the proximity sensor 100 is embedded in the mounting bracket E1 and the double nut E2. In this state, the proximity sensor 100 detects an embedded metal E such as the mounting bracket E1 and the double nut E2 which are not originally detected. Therefore, the proximity sensor 100 according to the embodiment of the invention is configured to suppress the influence of the embedded metal E in order to sufficiently extend the detection distance.

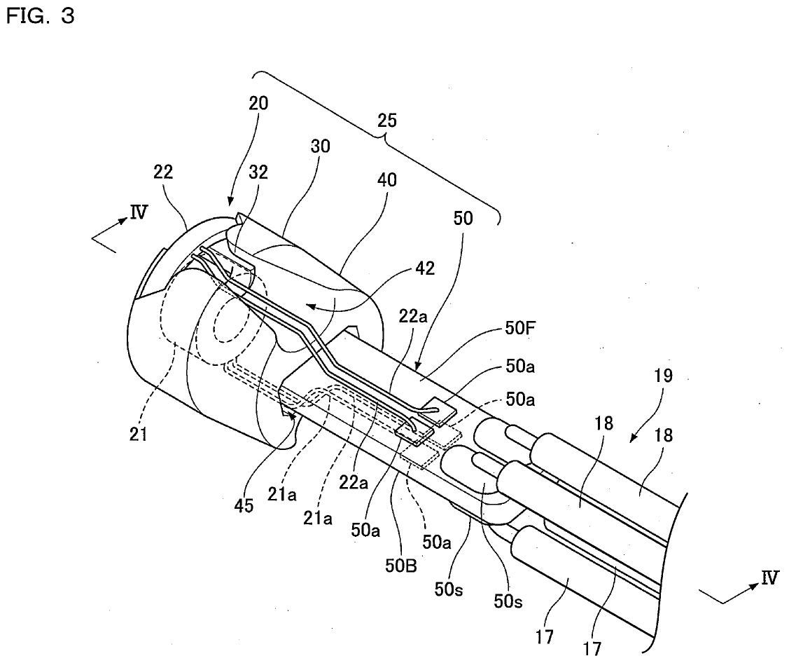

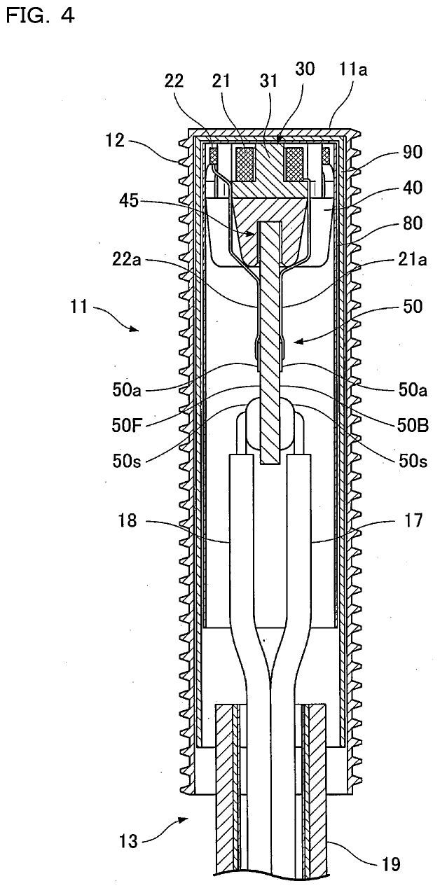

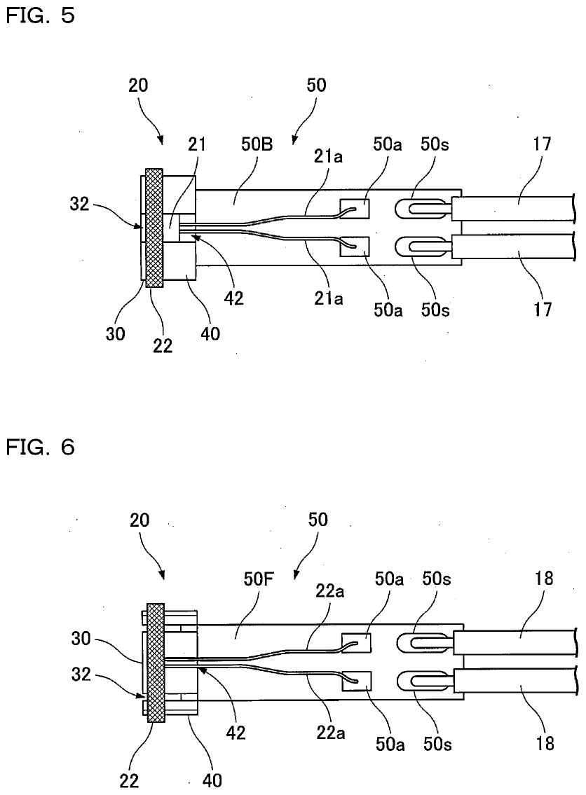

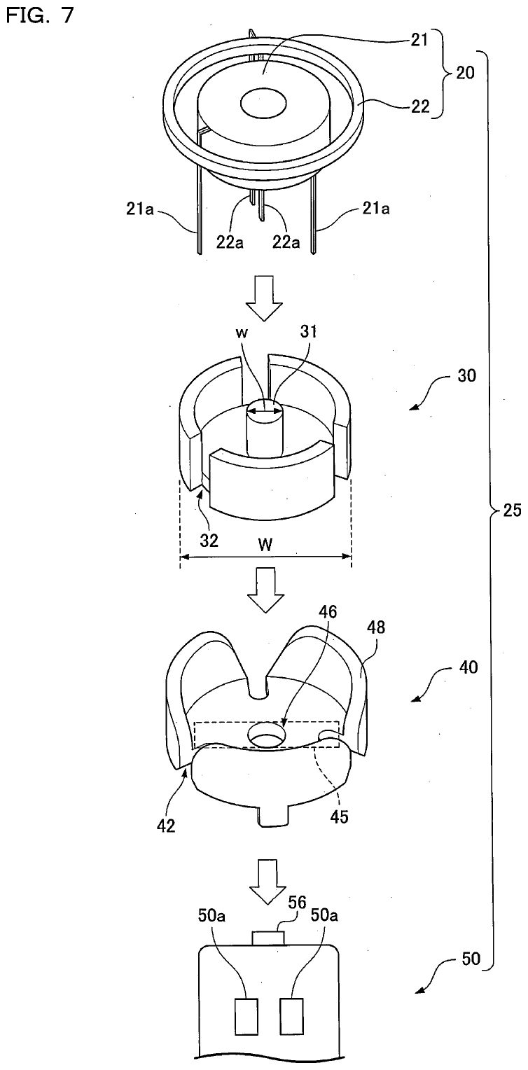

Hereinafter, configurations of the coil 20 and the in-head substrate 50 will be described with reference to FIGS. 3, 4, 5, and 6. FIG. 3 is a perspective view illustrating a bonding state between coil wires 21a and 22a and a substrate electrode 50a. FIG. 4 is a sectional view taken along line IV-IV of FIG. 3. FIG. 5 is a view illustrating wiring of the coil wire 21a from the first coil 21 to the substrate electrode 50a. FIG. 6 is a view illustrating wiring of the coil wire 22a from the second coil 22 to the substrate electrode 50a. Note that FIG. 5 illustrates one surface 50B of the in-head substrate 50, and FIG. 6 illustrates the other surface 50F of the in-head substrate 50.

FIGS. 3, 4, 5, and 6 illustrate the coil 20 and the in-head substrate 50 accommodated in the head housing 10 of the proximity sensor 100 in FIG. 1. The proximity sensor 100 includes a coil 20, a ferrite core 30, a core holder 40, and an in-head substrate 50. The coil 20, the ferrite core 30, the core holder 40, and the in-head substrate 50 are all accommodated in the head housing 10. Hereinafter, the coil 20, the ferrite core 30, the core holder 40, and the in-head substrate 50 may be collectively referred to as a sensor unit 25.

The coil 20 generates a magnetic field by an excitation current. The ferrite core 30 guides the magnetic field generated from the coil 20. The coil 20 includes a first coil 21 and a second coil 22. The second coil 22 is disposed outside the first coil 21 in the radial direction. The second coil 22 may be disposed concentrically with the first coil 21. In the present example, “disposed concentrically” indicates an arrangement relationship in which the circles are not limited to the objects on the same plane, and thus, in a case where the second coil 22 is disposed concentrically with respect to the first coil 21, the second coil 22 may be disposed on the side where a detection object D is detected (or the opposite side) with respect to the first coil 21. The first coil 21 is configured by winding the coil wire 21a. The second coil 22 is configured by winding the coil wire 22a. The magnetic field generated from the coil 20 is preferably guided toward the detection object. Since the ferrite core 30 includes the shaft body 31 and the shaft body 31 is directed to the detection object, the magnetic field generated near the shaft body 31 is easily guided to the detection object. Therefore, it is preferable that the first coil 21 configured to be closer to the shaft body 31 than the second coil 22 generates a magnetic field by the excitation current. Note that the ferrite core 30 in the present embodiment has the shaft body 31 around which the first coil 21 is wound and the peripheral wall (outer peripheral portion) that is located between the first coil 21 and the second coil 22 and is made of a magnetic material, but the ferrite core 30 may have only the shaft body 31. In addition, the shaft body 31 made of a magnetic material other than ferrite may be disposed. In addition, since the magnetic field itself is generated even without the ferrite core 30, the proximity sensor 100 may have a configuration without the ferrite core 30.

In order to ensure sufficient inductance, the number of windings of the first coil 21 is preferably 100 or more, and preferably 200 or more. When the number of windings of the first coil 21 is sufficiently large, the influence of the magnetic field generated from the first coil 21 by the pulsed excitation current passes through the head front surface portion 11a and reaches the distant detection object. Therefore, even if the surface of the head housing 10 facing the detection object is made of metal, the detection distance of the proximity sensor 100 becomes sufficiently large. When the linear shape of the coil wire 21a of the first coil 21 is sufficiently thin, for example, 0.02 mm or less, even if the diameter of the head front surface portion 11a of the head housing 10 is less than 8 mm, the first coil 21 having 200 or more turns can be accommodated in the head housing 10.

The core holder 40 holds the ferrite core 30. The core holder 40 positions the second coil 22 and fixes the ferrite core 30 to the in-head substrate 50. A substrate receiving portion 45 is formed in the core holder 40. When the end of the in-head substrate 50 is inserted into the substrate receiving portion 45, the in-head substrate 50 is fixed to the core holder 40. When the core holder 40 holds the ferrite core 30, the core holder 40 fixes the ferrite core 30 to the in-head substrate 50.

A slit 32 extending in the axial direction is formed in a part of the outer periphery of the ferrite core 30. A slit 42 extending in the axial direction is also formed in a part of the outer periphery of the core holder 40. The coil wire 21a of the first coil 21 and the coil wire 22a of the second coil 22 are drawn out to the in-head substrate 50 through the slit 32 of the ferrite core 30 and the slit 42 of the core holder 40.

The substrate electrode 50a is disposed on each of one surface 50B and the other surface 50F of the in-head substrate 50. In FIGS. 3, 4, 5, and 6, two substrate electrodes 50a are disposed on each of one surface 50B and the other surface 50F.

At least the coil wire 21a of the first coil 21 is preferably electrically connected to the in-head substrate 50 through direct bonding. In the present embodiment, both the coil wire 21a of the first coil 21 and the coil wire 22a of the second coil 22 are directly bonded to the substrate electrode 50a on the in-head substrate 50.

Direct bonding means that members to be bonded are directly bonded to each other without interposing a brazing material such as solder. For example, the coil wire 21a and the coil wire 22a are bonded to the substrate electrode 50a by a method such as resistance welding, pressure welding, ultrasonic bonding, or friction stir welding, whereby direct bonding is performed.

By performing the direct bonding, the problem of copper erosion in which copper of the conductive wire is dissolved in the solder is avoided even for the thin coil wire 21a and the thin coil wire 22a (for example, 0.02 mm or less). In addition, soldering the thin coil wire 21a and the thin coil wire 22a to the substrate electrode 50a has a high degree of difficulty in work, but the degree of difficulty in work is often lower in direct bonding than in soldering.

For example, in resistance welding, it is possible to perform direct bonding only by applying a current in a state where the coil wire 21a and the coil wire 22a are in contact with the substrate electrode 50a, and work is easier than soldering in which soldering needs to be performed by soldering.

An intermediary member may be interposed between the coil wire 21a of the first coil 21 (or the coil wire 22a of the second coil 22) and the in-head substrate 50. Even in a case where the coil wire 21a or the coil wire 22a and the intermediary member are directly bonded and the intermediary member is electrically connected to the in-head substrate 50, it can be said that the coil wire 21a or the coil wire 22a is electrically connected to the in-head substrate 50 through direct bonding.

When the coil wire 21a or the coil wire 22a is electrically connected to the in-head substrate 50 through direct bonding, the first coil 21 and the second coil 22 can be configured by the thin coil wire 21a and the thin coil wire 22a (for example, 0.02 mm or less). When the first coil 21 and the second coil 22 are constituted by the thin coil wire 21a and the thin coil wire 22a, even if the number of windings of the first coil 21 and the second coil 22 is large (for example, 100 or more, or 200 or more), the diameter dimension of the coil 20 becomes small. When the diameter dimension of the coil 20 is small, the proximity sensor 100 can have a small diameter (for example, the diameter of the head front surface portion 11a is less than 8 mm). If the number of windings of the first coil 21 is sufficiently large, the detection distance becomes sufficiently large even if the head front surface portion 11a is made of metal.

The coil wire 21a and the coil wire 22a are electrically connected to the cable 19 via the substrate electrode 50a and wiring (not illustrated) on the in-head substrate 50. The cable 19 includes a plurality of cable wires. In FIGS. 3, 4, 5, and 6, two first cable wires 17 electrically connected to the coil wire 21a of the first coil 21 and two second cable wires 18 electrically connected to the coil wire 22a of the second coil 22 are included in the cable 19.

The first cable wire 17 is connected to one surface 50B of the in-head substrate 50. The second cable wire 18 is connected to the other surface 50F of the in-head substrate 50. Connection between the first cable wire 17 and the second cable wire 18 and the in-head substrate 50 may be performed by soldering using solder 50s.

Since the first cable wire 17 and the second cable wire 18 are separately disposed on one surface 50B and the other surface 50F, respectively, the first coil 21 and the second coil 22 can be electrically connected to the cable 19 even if the dimension of the in-head substrate 50 is small. Therefore, even if the head housing 10 has a small diameter (for example, the diameter of the head front surface portion 11a is less than 8 mm), the dimension of the in-head substrate 50 can be set to a dimension capable of being accommodated in the head housing 10. One of the two first cable wires 17 may be electrically connected to one of the two coil wires 21a of the first coil 21, and the other one of the first cable wires 17 may be electrically connected to one of the two coil wires 22a of the second coil 22. In this case, the remaining one of the coil wires 21a of the first coil 21 and the remaining one of the coil wires 22a of the second coil 22 are connected to each of the two second cable wires 18. That is, the first cable wire 17 connected to the one surface 50B is not limited to being electrically connected to the coil wire 21a of the first coil 21, and the first cable wire 17 is preferably electrically connected to either the coil wire 21a of the first coil 21 or the coil wire 22a of the second coil 22. Similarly, the second cable wire 18 connected to the other surface 50F is preferably electrically connected to either the coil wire 21a of the first coil 21 or the coil wire 22a of the second coil 22.

Note that the coil wire 21a of the first coil 21 and the coil wire 22a of the second coil 22 may be electrically connected to the cable 19 via direct bonding without interposing the in-head substrate 50. For example, the coil wire 21a of the first coil 21 may be directly bonded to the first cable wire 17 without using the solder 50s. In addition, an intermediary member may be interposed between the coil wire 21a of the first coil 21 (or the coil wire 22a of the second coil 22) and the cable 19. Even in a case where the coil wire 21a or the coil wire 22a and the intermediary member are directly bonded and the intermediary member is electrically connected to the cable 19, it can be said that the coil wire 21a or the coil wire 22a is electrically connected to the cable 19 through direct bonding.

Next, configurations of the coil 20, the ferrite core 30, the core holder 40, and the in-head substrate 50 will be described with reference to FIG. 7. FIG. 7 is an exploded perspective view from the coil 20 constituting the proximity sensor 100 to the in-head substrate 50.

As illustrated in FIG. 7, the first coil 21 and the second coil 22 are concentrically disposed, and the second coil 22 is disposed outside the first coil 21 in the radial direction. In addition, the second coil 22 is shorter than the first coil 21 in a direction (axial direction) orthogonal to the radial direction thereof. That is, the axial dimension of the second coil is smaller than that of the first coil 21. With such a configuration, the second coil 22 has a lower sensitivity to the magnetic flux with respect to the first coil 21. For example, in a case where the first coil 21 is used to detect the detection object and the second coil 22 is used to detect the embedded metal E, it is preferable to reduce the influence of the magnetic flux passing through both the detection object and the embedded metal E on the detection result of the second coil 22. By reducing the sensitivity of the second coil 22 to the magnetic flux with respect to the first coil 21, the influence of the magnetic flux passing through both the detection object and the embedded metal E is reduced.

As illustrated in FIG. 7, the ferrite core 30 has a shaft body 31. The shaft body 31 passes through the hollow portion of the first coil 21. Hereinafter, in the radial direction, the ratio of the width w of the shaft body 31 to the entire width W of the ferrite core 30 may be referred to as a relative shaft width w/W.

A slit 32 extending in the axial direction is formed in a part of the outer periphery of the ferrite core 30. In FIG. 7, three slits 32 are formed. The coil wire 21a of the first coil 21 and the coil wire 22a of the second coil 22 pass through the slit 32. In FIG. 7, two of the coil wires 21a of the first coil 21 pass through the two slits 32 on the front side in the drawing, and two of the coil wires 22a of the second coil 22 pass through one slit 32 on the back side.

The core holder 40 is made of resin, for example. The slit 42 extending in the axial direction is formed in a part of the outer periphery of the core holder 40. In FIG. 7, three slits 42 are formed. The coil wire 21a of the first coil 21 and the coil wire 22a of the second coil 22 pass through the slit 42. In FIG. 7, two of the coil wires 21a of the first coil 21 pass through the two slits 42 on the front side in the drawing, and two of the coil wires 22a of the second coil 22 pass through one slit 42 on the back side.

The core holder 40 fixes the ferrite core 30 to the in-head substrate 50 by receiving the in-head substrate 50 with the recessed substrate receiving portion 45 formed on the lower surface while holding the ferrite core 30. Note that a holder hole 46 is formed at the center of the substrate receiving portion 45, and a substrate protrusion 56 formed at the tip of the in-head substrate 50 is inserted into the holder hole 46, whereby the in-head substrate 50 is fixed to the core holder 40. When the core holder 40 fixes the in-head substrate 50, positioning accuracy between the in-head substrate 50 and the coil 20 is enhanced, and the proximity sensor 100 can be manufactured in a space-saving manner.

An upper surface 48 of the circumferential edge portion of the core holder 40 supports the second coil 22. Since the upper surface 48 of the circumferential edge portion supports the second coil 22, the core holder 40 positions the second coil 22.

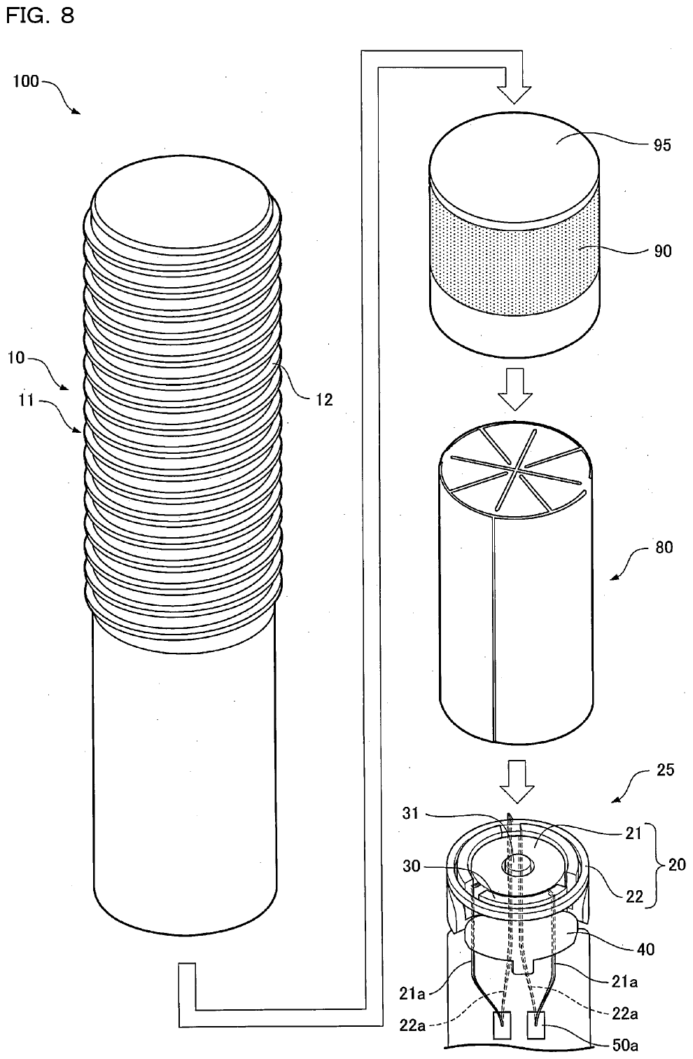

Next, the arrangement of the electric shield 80 and the magnetic shield 90 used for the proximity sensor 100 will be described with reference to FIG. 8. FIG. 8 is an exploded perspective view of components housed in the head housing 10 of the proximity sensor 100.

In addition to the sensor unit 25, an electric shield 80 and a magnetic shield 90 are further accommodated in the head housing 10 of the proximity sensor 100.

The electric shield 80 covers the sensor unit 25. The electric shield 80 completely covers the coil 20, the ferrite core 30, and the core holder 40 in the sensor unit 25, and partially covers the in-head substrate 50.

The magnetic shield 90 covers the sensor unit 25 together with the electric shield 80. The magnetic shield 90 partially covers the electric shield 80. The magnetic shield 90 completely covers the coil 20, the ferrite core 30, and the core holder 40 in the sensor unit 25, and partially covers the in-head substrate 50.

The head housing 10 has a housing body 11 in which an outer screw 12 is formed. As illustrated in FIG. 8, the housing body 11 completely covers the magnetic shield 90, the electric shield 80, and the sensor unit 25.

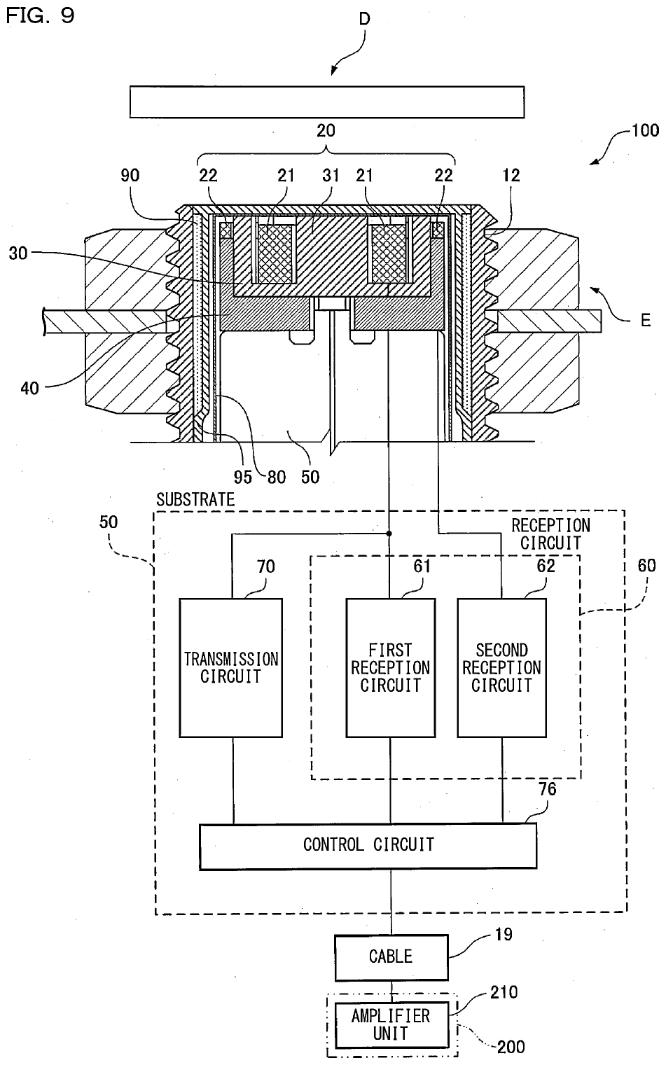

Hereinafter, a main circuit configuration of the proximity sensor 100 will be described with reference to FIG. 9. FIG. 9 is a block diagram for explaining a main circuit configuration of the proximity sensor 100.

As illustrated in FIG. 9, the proximity sensor 100 further includes a transmission circuit 70, a reception circuit 60, and a control circuit 76 as main circuit configurations.

The transmission circuit 70 periodically applies a pulsed excitation current to the coil 20. The coil 20 generates a magnetic field by periodically flowing a pulsed excitation current. The coil 20 includes a first coil 21 and a second coil 22. The second coil 22 is disposed outside the first coil 21 in the radial direction. The transmission circuit 70 may include, for example, an excitation circuit that generates a pulsed excitation current on the basis of a signal from the control circuit 76 and causes the pulsed excitation current to flow to the first coil 21. As illustrated in FIG. 9, a part (outer peripheral portion) of the ferrite core 30 is located between the first coil 21 and the second coil 22, but a magnetic material different from the ferrite core 30 may be located between the first coil 21 and the second coil 22. In any case, since the magnetic material is disposed between the first coil 21 and the second coil 22, the size (diameter dimension) of the entire coil 20 includes not only the sizes of the first coil 21 and the second coil 22 but also the size of the magnetic material. However, in the present embodiment, since the coil wire 21a of the first coil 21 and the coil wire 22a of the second coil 22 are thin, even if the number of windings is 100 or more (or 200 or more), the first coil 21 and the second coil 22 are small, and the entire coil 20 can be accommodated in a small head housing 10 having a diameter of less than 8 mm.

In a case where the detection object D is within the detection range, an eddy current is generated in the detection object D by the magnetic field generated from the coil 20. A magnetic field is generated from the detection object D by the eddy current of the detection object D. Here, since the excitation current flowing through the coil 20 is pulsed, the magnetic field generated from the coil 20 is rapidly weakened. Therefore, the eddy current of the detection object D also weakens, and accordingly, the magnetic field generated from the detection object D also weakens. In order to prevent the weakening of the magnetic field generated from the detection object D, a voltage or a current is generated in the coil 20.

The reception circuit 60 detects a voltage or a current generated in each of the first coil 21 and the second coil 22. Since the first coil 21 and the second coil 22 have different arrangements, characteristics of the generated voltage or current are also different. By detecting voltages or currents having different characteristics, an arithmetic operation for suppressing the influence of the embedded metal E becomes efficient. The reception circuit 60 may include, for example, a braking resistor that adjusts the current flowing from the coil 20, a filter circuit that performs filtering processing on the analog signal of the reception waveform, an amplifier circuit that amplifies the filtered analog signal, and an A/D conversion circuit that converts the amplified analog signal into a digital signal. Note that the reception circuit 60 may be configured to detect a voltage or a current generated in at least one of the first coil 21 and the second coil 22.

The control circuit 76 detects the detection object D on the basis of the change in the voltage or the current detected by the reception circuit 60. Preferably, the control circuit 76 detects the detection object D on the basis of a change in the voltage or the current generated in each of the first coil 21 and the second coil 22. As a result, the proximity sensor 100 can sufficiently extend the detection distance by suppressing the influence of the embedded metal E. The control circuit 76 is connected to the amplifier unit 210 of the amplifier housing 200 via the cable 19. The control circuit 76 may include, for example, an arithmetic circuit that performs an arithmetic operation for detecting the detection object D on the basis of at least one of the first reception waveform and the second reception waveform, and an output circuit that outputs a result of the arithmetic operation of the arithmetic circuit to the outside (such as the amplifier unit 210) via the cable 19.

In the example illustrated in FIG. 9, the first coil 21 generates a magnetic field by periodically flowing a pulsed excitation current from the transmission circuit 70. In the present embodiment, only the first coil 21 generates the magnetic field by the excitation current, but the coil 20 that generates the magnetic field by the excitation current may be only the second coil 22, or may be both the first coil 21 and the second coil 22. In a case where an excitation current is applied to only one of the first coil 21 and the second coil 22 to generate a magnetic field, it is preferable to apply an excitation current only to the first coil 21 to generate a magnetic field. As described above, the detection result by the first coil 21 is different from the detection result by the second coil 22, but in order to extend the detection distance, it is preferable that both detection results are easily affected by the detection object D. In a case where the magnetic field generated from the coil 20 is directed to a range in which the detection object D can be located, that is, a detection range, the detection result by the coil 20 is easily affected by the detection object D. The coil 20 through which the excitation current flows is preferably a coil wound close to a shaft body 31 of the ferrite core 30 to generate a magnetic field by causing the excitation current to flow through the first coil 21 since the generated magnetic field is easily directed to the detection range. In addition, in a case where an excitation current is caused to flow through both the first coil 21 and the second coil 22 to generate a magnetic field, for example, by directing the direction of the magnetic field of the first coil 21 to the detection object D and directing the direction of the magnetic field of the second coil 22 to the embedded metal E, it is possible to obtain a detection result in which the magnetic field of the first coil 21 and the magnetic field of the second coil 22 interfere with each other and the influence of the embedded metal E is reduced.

In the example illustrated in FIG. 9, the transmission circuit 70, the reception circuit 60, and the control circuit 76 are provided on the in-head substrate 50. By providing the transmission circuit 70, the reception circuit 60, and the control circuit 76 on the in-head substrate 50, the circuit configuration is stabilized. The transmission circuit 70, the reception circuit 60, and the control circuit 76 are not limited to being provided on the in-head substrate 50. For example, the transmission circuit 70, the reception circuit 60, and the control circuit 76 may be provided in another member, for example, the amplifier housing 200. Furthermore, any one or two of the transmission circuit 70, the reception circuit 60, and the control circuit 76 may be provided on the in-head substrate 50, and other circuits may be provided on another substrate (a substrate disposed inside or outside the head housing 10, for example, a substrate in the amplifier housing 200).

The reception circuit 60 includes a first reception circuit 61 and a second reception circuit 62. The first reception circuit 61 detects a voltage or a current generated in the first coil 21. The second reception circuit 62 detects a voltage or a current generated in the second coil 22. Hereinafter, the temporal change of the voltage or the current detected by the reception circuit 60 may be referred to as a reception waveform. The temporal changes of the voltage or the current detected by the first reception circuit 61 and the second reception circuit 62 may be referred to as a first reception waveform and a second reception waveform, respectively.

Since the reception circuit 60 includes the first reception circuit 61 and the second reception circuit 62, it is not necessary to switch the reception circuit 60 between the case of detecting the voltage or the current generated in the first coil 21 and the case of detecting the voltage or the current generated in the second coil 22. That is, since the reception circuit 60 includes the first reception circuit 61 and the second reception circuit 62, it is possible to simultaneously detect a voltage or a current generated in the first coil 21 and a voltage or a current generated in the second coil 22. Therefore, the proximity sensor 100 can sufficiently extend the detection distance by improving the detection accuracy.

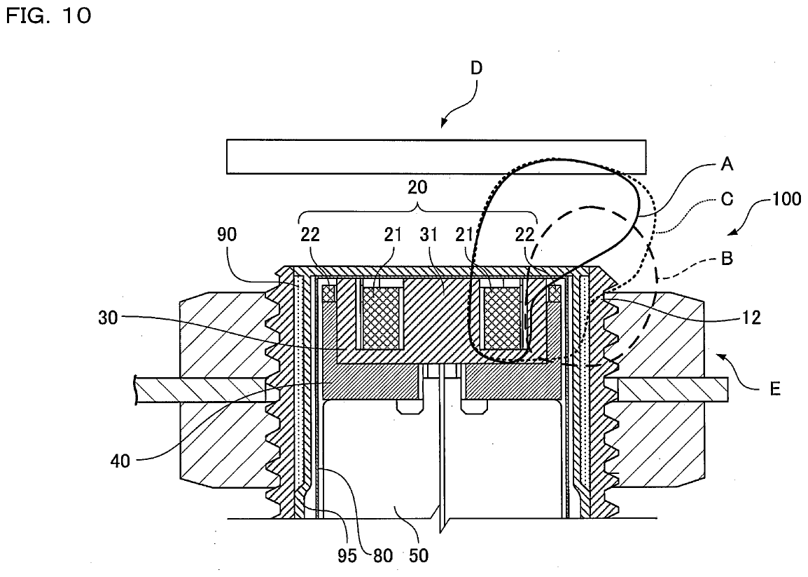

Hereinafter, a magnetic field and a magnetic flux line thereof will be described with reference to FIG. 10. FIG. 10 is a diagram schematically illustrating magnetic flux lines around the first coil 21 and the second coil 22.

As illustrated in FIG. 10, the core holder 40 holds the ferrite core 30 and positions the second coil 22. When the core holder 40 positions the second coil 22, the arrangement of the second coil 22 is stabilized regardless of the ferrite core 30. As the arrangement of the second coil 22 is stabilized, the second reception waveform is stably detected. Therefore, the proximity sensor 100 can sufficiently extend the detection distance by suppressing the influence of the embedded metal E.

In addition, since the axial dimension of the second coil 22 is smaller than the axial dimension of the first coil 21, the magnetic flux lines passing through the embedded metal E are reduced. Therefore, the proximity sensor 100 can sufficiently extend the detection distance by suppressing the influence of the embedded metal E.

The second coil 22 is located on the side (distal end side) where the detection object D is detected with respect to the first coil 21. Since the second coil 22 is located on the distal end side of the first coil 21, the magnetic flux lines passing through the embedded metal E are reduced. Therefore, the proximity sensor 100 can sufficiently extend the detection distance by suppressing the influence of the embedded metal E.

The second coil 22 is preferably located on the distal end side. This is because the magnetic flux lines passing through the embedded metal E decrease as the second coil 22 is located on the more distal end side. Therefore, it is more preferable that the second coil 22 abuts on a member on the most distal end side of the proximity sensor 100.

In FIG. 10, the magnetic flux line received only by the first coil 21 is indicated by a thick line of a symbol A, the magnetic flux line received only by the second coil 22 is indicated by a broken line of a symbol B, and the magnetic flux lines received by both the first coil 21 and the second coil 22 are indicated by a dotted line of a symbol C.

The magnetic flux line (thick line: symbol A) received only by the first coil 21 has a high rate of generating a reception waveform based on the detection object D. The magnetic flux line (broken line: symbol B) received only by the second coil 22 has a high rate of generating a reception waveform based on the embedded metal E. The magnetic flux lines (dotted line: symbol C) received by both the first coil 21 and the second coil 22 have a high rate of generating a reception waveform based on both the detection object D and the embedded metal E.

Therefore, by reducing the magnetic flux lines (dotted line: symbol C) received by both the first coil 21 and the second coil 22, the respective ratios of the reception waveform based on the detection object D and the reception waveform based on the embedded metal E relatively increase. When the ratio between the reception waveform based on the detection object D and the reception waveform based on the embedded metal E increases, the reception waveform based on the embedded metal E can be easily grasped, leading to reduction of the influence of the embedded metal E.

As compared with FIG. 10, the magnetic flux lines (dotted line: symbol C) received by both the first coil 21 and the second coil 22 form a path avoiding the embedded metal E. In order to achieve the state illustrated in FIG. 10, the magnetic shield 90 and the ferrite core 30 are appropriately provided.

As illustrated in FIG. 10, by appropriately arranging the magnetic shield 90, the magnetic flux lines (dotted line: symbol C) received by both the first coil 21 and the second coil 22 form a path that further avoid the embedded metal E. This is because the magnetic shield 90 guides the magnetic flux lines with relative magnetic permeability of a certain degree or more.

By forming the ferrite core 30 into an appropriate shape, the magnetic flux lines (dotted line: symbol C) received by both the first coil 21 and the second coil 22 form a path that further avoids the embedded metal E. This is because the shape of the ferrite core 30 causes the magnetic flux lines to further face the distal end side.

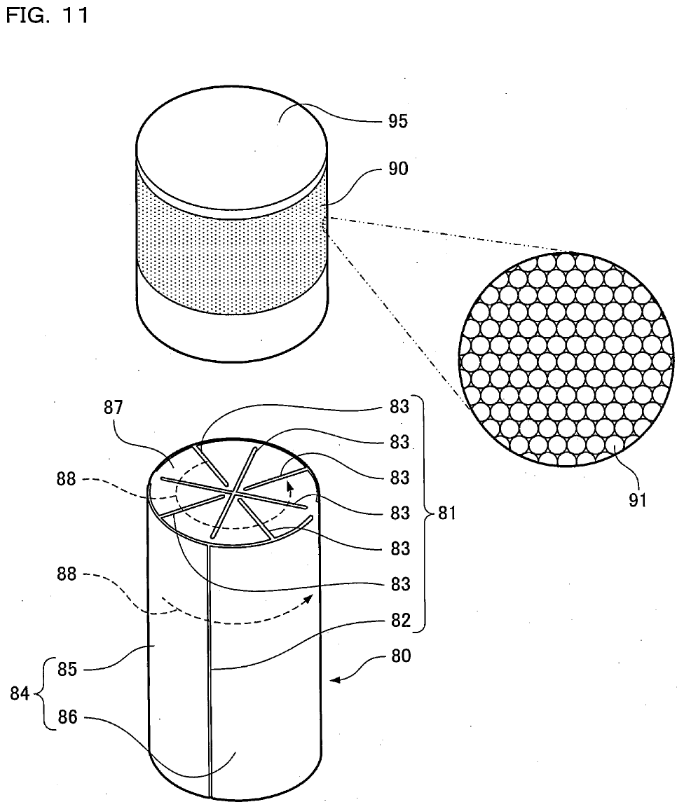

Hereinafter, the magnetic shield 90 will be described in detail with reference to FIGS. 10 and 11. FIG. 11 is an exploded perspective view for explaining the electric shield 80 and the magnetic shield 90 in detail.

As illustrated in FIG. 10, the magnetic shield 90 is disposed outside the second coil 22 in the radial direction. With this arrangement, the magnetic flux lines (dotted line: symbol C) received by both the first coil 21 and the second coil 22 are guided along the magnetic shield 90, so that a path that further avoids the embedded metal E is obtained. Therefore, the proximity sensor 100 can sufficiently extend the detection distance by suppressing the influence of the embedded metal E.

In the proximity sensor 100, the magnetic shield 90 is more preferable toward the outer side in the radial direction. This is because the magnetic flux lines (dotted line: symbol C) received by both the first coil 21 and the second coil 22 are guided in a direction to further avoid the embedded metal E. For example, the magnetic shield 90 is disposed outside the electric shield 80 (and inside the head housing 10) in the radial direction. The magnetic shield 90 may constitute the head housing 10.

As illustrated in FIG. 11, the magnetic shield 90 includes a sheet member kneaded with ferromagnetic powder 91 (for example, metal powder). Since the magnetic shield 90 is formed of a sheet member kneaded with the ferromagnetic powder 91, the magnetic shield has a relative magnetic permeability higher (to some extent or more) than air and a low electric conductivity. The sheet member may be formed by compacting the ferromagnetic powder 91. The magnetic shield 90 appropriately guides the magnetic flux lines with relative magnetic permeability higher than air. The magnetic shield 90 has a low electrical conductivity, so that an eddy current loop in the magnetic shield 90 can be suppressed without performing insulation treatment. By suppressing the eddy current loop, noise to the reception waveform is suppressed. Therefore, the proximity sensor 100 including such a magnetic shield 90 can sufficiently extend the detection distance by improving the detection accuracy.

The ferromagnetic powder 91 constituting the magnetic shield 90 is, for example, iron powder. Since the magnetic shield 90 is formed of a sheet member kneaded with iron powder, the magnetic shield has a relatively high relative magnetic permeability (about 200 to 300). The sheet member kneaded with iron powder is, for example, an electromagnetic wave absorbing sheet. In this example, a sheet member kneaded with the ferromagnetic powder 91 is used as the magnetic shield 90, but the entire magnetic shield 90 may be an amorphous ferromagnetic member. For example, it may be amorphous.

Note that a permalloy sheet, a cobalt sheet, or the like is not suitable as the magnetic shield 90. This is because a permalloy sheet, a cobalt sheet, or the like has a high relative magnetic permeability (about 1000 to several tens of thousands) but has a high electrical conductivity. The high electrical conductivity leads to the generation of the eddy current loop.

The magnetic shield 90 is wound around an outer periphery of a resin cap 95 having a bottomed cylindrical shape. The resin cap 95 has a function of protecting a member accommodated inside the resin cap 95. The magnetic shield 90 is wound around the outer periphery of the resin cap 95, whereby the arrangement on the outer side in the radial direction is stabilized. Instead of the resin cap 95 made of resin, a cap other than resin may be used. The magnetic shield 90 is disposed outside the cap regardless of whether or not the cap is made of resin.

Hereinafter, details of the electric shield 80 will be described with reference to FIG. 11. The electric shield 80 is a bottomed cylindrical metal body that protects the coil 20 and the ferrite core 30 from external noise.

As illustrated in FIG. 11, the electric shield 80 is disposed outside the second coil 22 in the radial direction. A cut 81 is formed in the electric shield 80. The cut 81 is transverse to a direction 88 around the axis of the electric shield 80. Specifically, the longitudinal direction of the cut 81 intersects (preferably is orthogonal to) the direction 88 around the axis.

By the cut 81 intersecting the direction 88 around the axis of the electric shield 80, a loop of an eddy current which is a current around the axis is suppressed in the electric shield 80. By suppressing the eddy current loop, noise to the reception waveform is suppressed. Therefore, the proximity sensor 100 including such an electric shield 80 can sufficiently extend the detection distance by improving the detection accuracy.

The electric shield 80 includes a peripheral portion 84 and a detection surface portion 87. The peripheral portion 84 covers the second coil 22 from the outside in the radial direction. The detection surface portion 87 closes the distal end side which is one end of the peripheral portion 84. The detection surface portion 87 is located on the side where the detection object D is detected.

The cut 81 has a peripheral cut 82 and a detection surface cut 83. The peripheral cut 82 is formed in the peripheral portion 84. The detection surface cut 83 is formed in the detection surface portion 87.

By the peripheral cut 82, an eddy current loop is suppressed in the peripheral portion 84. The peripheral cut 82 facilitates the manufacture of the electric shield 80. The detection surface cut 83 efficiently suppresses the eddy current loop in the detection surface portion 87.

The electric shield 80 has a sheet metal configuration. That is, the electric shield 80 is obtained by bending a thin metal plate. Since the electric shield 80 has the sheet metal configuration, the shape is stabilized even if the strength is reduced due to the cut 81. The thin metal plate before being bent as the electric shield 80 may be punched out. The electric shield 80 has a bottomed cylindrical three-dimensional shape by pressing the punched thin metal plate. That is, the electric shield 80 may be a press-molded product of a punched thin metal plate. The shape of such an electric shield 80 is further stabilized even if the strength is reduced by the cut 81. The thin metal plate constituting the electric shield 80 may be, for example, copper foil or brass foil. The electric shield 80 is not limited to the sheet metal configuration. For example, the electric shield 80 may be a coating molded product or a vapor deposition molded product. The coating molded product or the vapor deposition molded product is molded by applying or vapor depositing a conductive material on a bottomed cylindrical resin mold. Since a current flows through the electric shield 80, the electric shield 80 is preferably electrically connected to the ground (GND, reference potential). In the present embodiment, for example, a shielded cable (not illustrated) serving as a reference potential is included in the first cable wire 17, and the shielded cable is electrically connected to the electric shield 80.

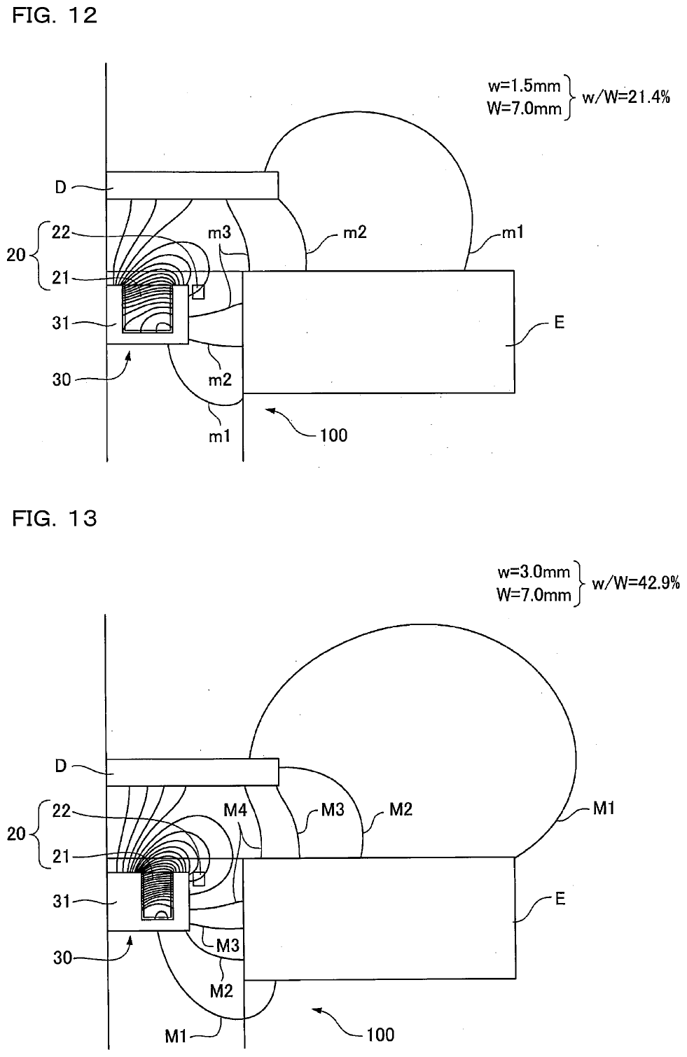

Hereinafter, the ferrite core 30 will be described in detail with reference to FIGS. 12 and 13. FIG. 12 is a magnetic flux diagram in a case where the shaft body 31 of the ferrite core 30 is thin. FIG. 13 is a magnetic flux diagram in a case where the shaft body 31 of the ferrite core 30 is not thin. FIG. 12 illustrates magnetic flux lines in a case where the width w of the shaft body 31 in the radial direction is 1.5 mm in the electromagnetic field simulation, and FIG. 13 illustrates magnetic flux lines in a case where the width w of the shaft body 31 in the radial direction is 3 mm in the electromagnetic field simulation.

In the example illustrated in FIG. 12, the width w of the shaft body 31 is 1.5 mm and the width W of the entire ferrite core 30 is 7 mm in the radial direction, and the relative shaft width w/W is 21.4%. That is, the relative shaft width w/W is 30% or less. As illustrated in FIG. 12, three magnetic flux lines m1 to m3 pass through the embedded metal E.

On the other hand, in the example illustrated in FIG. 13, the width w of the shaft body 31 is 3 mm and the width W of the entire ferrite core 30 is 7 mm in the radial direction, and the relative shaft width w/W is 42.9%. That is, the relative shaft width w/W is more than 30%. As illustrated in FIG. 13, four magnetic flux lines M1 to M4 pass through the embedded metal E.

As is clear from the comparison between FIGS. 12 and 13, in FIG. 12 in which the relative shaft width w/W has been 30% or less, the number of magnetic flux lines passing through the embedded metal E has been as small as 3, and in FIG. 13 in which the relative shaft width w/W has been more than 30%, the number of magnetic flux lines passing through the embedded metal E has been as large as 4. Therefore, it is found that the influence of the embedded metal E is suppressed when the relative shaft width w/W is 30% or less.

When the relative shaft width w/W is less than 15%, it is difficult to manufacture the ferrite core 30. Therefore, it can be said that the relative shaft width w/W is preferably 30% or less, and more preferably 15% or more and 30% or less.

The embodiment is illustrative in all respects and is not restrictive. The scope of the invention is indicated not by the above description but by the claims, and it is intended that meanings equivalent to the claims and all modifications within the scope are included. Among the configurations described in the embodiment, configurations other than the configuration described as one aspect of the invention in “means for solving problems” are arbitrary configurations, and can be appropriately deleted and changed.
(1) In the embodiment, the magnetic shield 90 and the electric shield 80 are illustrated as cylindrical shapes, but may have other shapes such as a square tube shape.
(2) Although the mounting bracket E1 and the double nut E2 have been described as the embedded metal E in which the proximity sensor 100 is embedded, other metals may be used. The other metal is a single nut, a metal block on which an inner screw is formed, or the like. The embedded metal E is merely metal in which the proximity sensor 100 is embedded, and is not a configuration of the proximity sensor 100 itself.
(3) In the embodiment, the transmission circuit 70 is illustrated as one, but the transmission circuit 70 may include a first transmission circuit and a second transmission circuit. The first transmission circuit periodically applies a pulsed excitation current to the first coil 21, and the second transmission circuit periodically applies a pulsed excitation current to the second coil 22.

The invention provides a proximity sensor, and has industrial applicability.

What is claimed is:

1. A proximity sensor comprising:
a coil that generates a magnetic field by an excitation current;
a ferrite core that guides the magnetic field generated from the coil;
a head housing that accommodates the coil and the ferrite core; and
an in-head substrate that is accommodated in the head housing, wherein
the coil includes:
a first coil; and
a second coil disposed concentrically with the first coil,
the proximity sensor further comprises:
a transmission circuit that periodically applies a pulsed excitation current to the coil;
a reception circuit that detects a voltage or a current generated in at least one of the first coil and the second coil by the magnetic field which is changed by a detection object; and
a control circuit that detects the detection object on a basis of a change in the voltage or the current detected by the reception circuit, and
a coil wire of the first coil is electrically connected to the in-head substrate via direct bonding.

2. The proximity sensor according to claim 1, wherein the transmission circuit, the reception circuit, and the control circuit are provided on the in-head substrate.

3. The proximity sensor according to claim 1, further comprising:
a cable that extends from the head housing; and
an amplifier housing that is connected to the head housing via the cable, wherein
the transmission circuit, the reception circuit, and the control circuit are provided in the amplifier housing.

4. The proximity sensor according to claim 1, wherein
the reception circuit includes:
a first reception circuit that detects a voltage or a current generated in the first coil; and
a second reception circuit that detects a voltage or a current generated in the second coil, wherein
the control circuit detects the detection object on a basis of a difference between the voltage or the current detected by the first reception circuit and the voltage or the current ditected by the second reception circuit.

5. The proximity sensor according to claim 1, wherein the second coil is shorter than the first coil in a direction orthogonal to a radial direction of the second coil.

6. The proximity sensor according to claim 5, wherein the second coil is disposed outside the first coil in the radial direction.

7. The proximity sensor according to claim 1, wherein the second coil is located closer to a side where the detection object is detected than the first coil.

8. The proximity sensor according to claim 1, further comprising
a core holder that holds the ferrite core, wherein
the core holder positions the second coil and fixes the ferrite core to the in-head substrate.

9. The proximity sensor according to claim 1, further comprising a magnetic shield that is disposed outside the second coil in a radial direction, wherein
the magnetic shield includes a sheet member kneaded with ferromagnetic powder.

10. The proximity sensor of claim 1, further comprising
an electric shield that is disposed outside the second coil in a radial direction, wherein
the electrical shield is formed with a cut across a direction around an axis of the electric shield.

11. The proximity sensor according to claim 10, wherein
the electric shield includes:
a peripheral portion covering the second coil from an outside of the second coil in the radial direction; and
a detection surface portion located on a side where the detection object is detected,
the cut is formed in the detection surface portion, and
the electrical shield is a press-molded product of a punched thin metal plate.

12. The proximity sensor according to claim 11, wherein the cut is formed in the peripheral portion.

13. The proximity sensor according to claim 1, wherein
the ferrite core has a shaft body passing through a hollow portion of the first coil, and
a ratio of a width of the shaft body to an entire width of the ferrite core in a radial direction of the first coil is 30% or less.

14. The proximity sensor according to claim 13, wherein a ratio of a width of the shaft body to an entire width of the ferrite core in a radial direction of the first coil is 15% or more.

15. The proximity sensor according to claim 1, wherein
the cable includes a first cable wire electrically connected to either a coil wire of the first coil or a coil wire of the second coil, and a second cable wire electrically connected to either a coil wire of the first coil or a coil wire of the second coil,
the first cable wire is connected to one surface of the in-head substrate, and
the second cable wire is connected to another surface of the in-head substrate.

16. A proximity sensor comprising:
a coil that generates a magnetic field by an excitation current;
a ferrite core that guides the magnetic field generated from the coil;
a head housing that accommodates the coil and the ferrite core; and
a cable that extends from the head housing, wherein
the coil includes:
a first coil; and
a second coil disposed concentrically with the first coil,
the proximity sensor further comprises:
a transmission circuit that periodically applies a pulsed excitation current to the coil;
a reception circuit that detects a voltage or a current generated in at least one of the first coil and the second coil by the magnetic field which is changed by a detection object; and
a control circuit that detects the detection object on a basis of a change in the voltage or the current detected by the reception circuit, and
a coil wire of the first coil is electrically connected to the cable via direct bonding.

17. A proximity sensor comprising:
a coil that generates a magnetic field by an excitation current;
a ferrite core that guides the magnetic field generated from the coil; and
a head housing that accommodates the coil and the ferrite core, wherein
the coil includes:
a first coil;
a second coil disposed outside the first coil in a radial direction; and
a magnetic material that is located between the first coil and the second coil,
the proximity sensor further comprises:
a transmission circuit that periodically applies a pulsed excitation current to the coil;
a reception circuit that detects a voltage or a current generated in at least one of the first coil and the second coil by the magnetic field which is changed by a detection object; and
a control circuit that detects the detection object on a basis of a change in the voltage or the current detected by the reception circuit,
a diameter of a surface of the head housing capable of facing the detection object is less than 8 mm, and
a number of windings of the first coil is 100 or more.

18. The proximity sensor according to claim 17, wherein a surface of the head housing capable of facing the detection object is made of metal.

19. The proximity sensor according to claim 17, wherein a wire diameter of a coil wire of the first coil is 0.02 mm or less.

20. The proximity sensor according to claim 17. further comprising
an in-head substrate that is accommodated in the head housing, wherein
a coil wire of the first coil is electrically connected to the in-head substrate via direct bonding.
